(19) United States
(12) Patent Application Publication
(10) Pub. No.: US 2008/0316720 A1
(43) Pub. Date: Dec. 25, 2008

(54) Electronic components

(76) Inventor: Kazuhiro Maeno, Kariya-shi (JP)

Correspondence Address: MORGAN & FINNEGAN, L.L.P., 3 WORLD FINANCIAL CENTER, NEW YORK, NY, 10281-2101, US

(21) Appl. No.: 12/148,560

(22) Filed: Apr. 21, 2008

(30) Foreign Application Priority Data
Apr. 25, 2007 (JP) 2007-115624

(51) Int. Cl. H05K 5/00

(52) U.S. Cl. 361/757

(57) ABSTRACT

Electronic components include a case, a circuit board, electronic parts, a plate-like electrode terminal, a metal cover, a stepped portion, a connecting terminal, and a fastening member. The case includes a connector portion and an opening. The connector portion has an external terminal. The circuit board mounting the electronic parts is accommodated in the case. The electrode terminal is accommodated in the case and electrically connected to the electronic parts. The plate-like electrode terminal includes a board-side end portion and a case-side end portion. The metal cover closes the opening so as to be spaced away from the circuit board and the electrode terminal. The connecting terminal is arranged on a stepped portion in the case. The connecting terminal is formed integrally with the external terminal. The fastening member connects the case-side end portion to the case. The fastening member electrically connects the case-side end portion to the connecting terminal.

### BACKGROUND OF THE INVENTION

The present invention relates to electronic components wherein a circuit board mounting electronic parts is accommodated in a case.

Electronic components having a hermetical case and a connector have been offered in the electronics field. The electronic components include the case for accommodating a circuit board on which electronic parts are mounted. The case is hermetically closed by covering an opening with a cover. The connector is formed at a side wall of the case so that the connector is electrically connectable to an external device. In such electronic components, the electronic parts accommodated in the case is electrically connected to a terminal of the connector so that electric current is supplied to the electronic parts.

As an example of such electronic components, a semi-conductor device is disclosed in Japanese Patent Application Publication No. 6-224314. The semi-conductor device includes a case for hermetically accommodating a thick film circuit board on which electronic parts are mounted. The case includes an external connecting terminal formed integrally therewith. The external connecting terminal is electrically connectable to an external device. In the semi-conductor device, a metal base plate is attached to an end of the cylindrical case to close an opening of the case. The thick film circuit board on which electronic parts are mounted is arranged on the surface of the metal base plate. The thick film circuit board is electrically connected to an input-output terminal. The input-output terminal is electrically connected to the external connecting terminal by wire bonding with lead wire. Thereby, the electronic parts are electrically connectable to the external device through the external connecting terminal.

However, in the semi-conductor device of the above reference, consideration is not given to a state when large current, for example, of 10 ampere from the external device is supplied to the electronic parts hermetically accommodated in the case. That is, the semi-conductor device utilizes a lead wire in wire bonding to electrically connect the external connecting terminal with the input-output terminal of the thick film circuit board. Therefore, large current cannot be supplied to the electronic parts through the external connecting terminal.

Further, the above reference does not describe that the semi-conductor device is attached to an object, such as a vehicle frame. In the semi-conductor device, the metal base plate on which the thick film circuit board is attached serves as a bottom wall portion of the semi-conductor device. The metal base plate is attached to the object in a state directly contacting to the object. Therefore, when the semi-conductor device is attached to the vehicle frame by screwing, a metal attaching portion is attached by pressing, and that causes the attaching portion to be deformed, thereby the circuit board on the attaching portion is deformed. That may cause problems in the electrically-connected structure of the electronic parts mounted on the circuit board.

Additionally, when the semi-conductor device is attached to a part which is to be vibrated frequently, such as a vehicle frame, the vibration may be transferred through the attaching portion to the circuit board. The vibration in the circuit board may generate unnecessary stress. Due to the unnecessary stress, the circuit board may be deformed, and that may cause problems in the electrically-connected structure of the mounted electronic parts.

The present invention is directed to electronic components in which large current is to be supplied to electronic parts, and unnecessary stress on the circuit board is reduced.

### SUMMARY OF THE INVENTION

In accordance with an aspect of the present invention, electronic components include a case, a circuit board, electronic parts, a plate-like electrode terminal, a metal cover, a stepped portion, a connecting terminal, and a fastening member. The case includes a connector portion and an opening. The connector portion has an external terminal therein. The circuit board is accommodated in the case. The electronic parts are mounted on the circuit board. The plate-like electrode terminal is accommodated in the case and electrically connected to the electronic parts. The plate-like electrode terminal includes a board-side end portion and a case-side end portion. The board-side end portion is connected to the circuit board. The metal cover is attached to the case to close the opening of the case such that the metal cover is spaced away from the circuit board and the electrode terminal. The stepped portion is formed in the case. The connecting terminal is arranged on the stepped portion. The connecting terminal is formed integrally with the external terminal. The fastening member connects the case-side end portion to the case. The fastening member electrically connects the case-side end portion to the connecting terminal.

Other aspects and advantages of the invention will become apparent from the following description, taken in conjunction with the accompanying drawings, illustrating by way of example the principles of the invention.

### BRIEF DESCRIPTION OF THE DRAWINGS

The features of the present invention that are believed to be novel are set forth with particularity in the appended claims. The invention together with objects and advantages thereof, may best be understood by reference to the following description of the presently preferred embodiments together with the accompanying drawings in which:

FIG. 1 is an exploded perspective view of electronic components according to a preferred embodiment of the present invention;

FIG. 2A is a partial cross-sectional view of the electronic components in a state where a metal plate is not attached;

FIG. 2B is a plan view of the electronic components in a state where the metal plate is not attached;

FIG. 3 is a plan view of the electronic components in a state where the electronic components are attached to a vehicle frame.

### DETAILED DESCRIPTION OF THE PREFERRED EMBODIMENTS

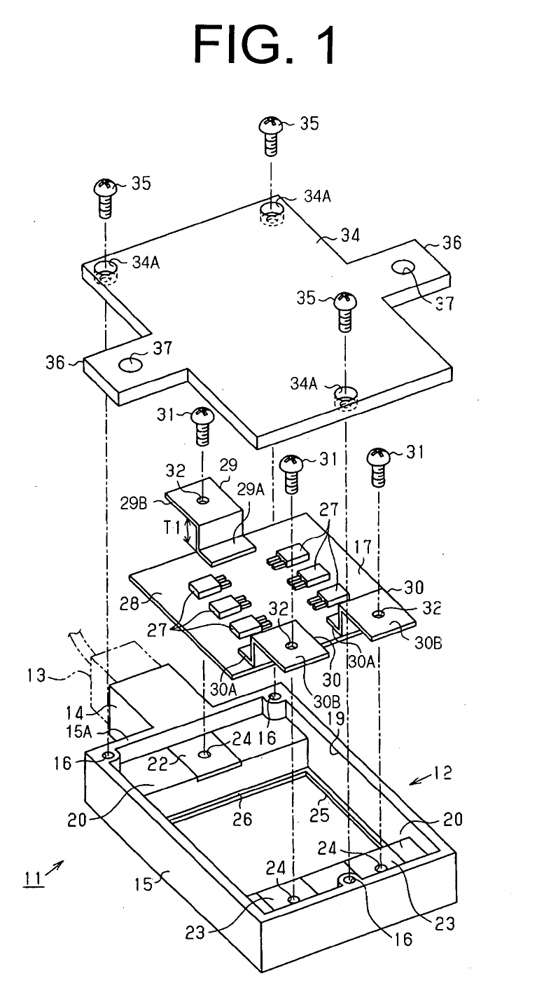

The following will describe a preferred embodiment of electronic components according to the present invention with reference to FIGS. 1 through 3.

As shown in FIG. 1, electronic components 11 include a case 12. The case 12 is made of resin and is formed in a rectangular shape in a plan view. A connector portion 14 is formed integrally with the case 12 so as to protrude from a peripheral wall 15 of the case 12. The connector portion 14 is connectable to a connector 13 of an external device which is not shown. The connector portion 14 includes therein an external terminal 14A. The case 12 has two pairs of parallel sides. In the case 12, plural first screw holes 16 are formed at an end face 15A of the peripheral wall 15. Two of the first screw holes 16 are formed at two corners adjacent to the connector portion 14. Another first screw hole 16 is formed at the middle of the short side which is parallel to the side defined by the two corners. A printed circuit board 17 is to be accommodated in the case 12. The printed circuit board 17 is formed in a rectangular shape in a plan view. The case 12 has an opening 19 at the top end. The top opening 19 has a larger cross-sectional area than the printed circuit board 17 in the plan view. A stepped portion 20 is formed at each longitudinal end of the rectangular case 12, and is extended along each short side, respectively.

Connecting terminals, that is, an anode-connecting terminal 22 and two cathode-connecting terminals 23 are arranged on the stepped portions 20 in this embodiment. The anode-connecting terminal 22 is arranged on one of the stepped portions 20 adjacent to the connector portion 14 at the middle in the longitudinal direction of the stepped portion 20. The cathode-connecting terminals 23 are arranged on the other of the stepped portions 20 opposite to the connector portion 14. The cathode-connecting terminals 23 are spaced apart from each other in the longitudinal direction of the stepped portion 20.

The anode-connecting terminal 22 and the cathode-connecting terminals 23 are formed in a plate-like shape, and have corresponding second screw holes 24. The connecting terminals 22, 23 are formed integrally with the external terminal 14A of the connector portion 14 so as to be electrically connected thereto. Connecting portion between the connecting terminals 22, 23 and the external terminal 14A of the connector portion 14 are inserted into the case 12 with insert molding.

The case 12 has a bottom opening 25 so as to open the inside of the case 12 to the external air. The bottom opening 25 is formed in a rectangular shape in the plan view, and has a slightly smaller cross-sectional area than the printed circuit board 17. The bottom opening 25 is positioned so as to face the top opening 19. A peripheral portion 26 is formed around the bottom opening 25 at the bottom of the case 12 so that the periphery of the rear surface (the opposite surface to a mounting surface 28) of the printed circuit board 17 is supported by the peripheral portion 26. At least a part of the rear surface of the printed circuit board 17 is exposed to the external air through the bottom opening 25. The periphery of the rear surface of the printed circuit board 17 is adhered to the peripheral portion 26 at the bottom of the case 12 by an adhesive. Thereby the inside of the case 12 is reliably hermetically closed.

The printed circuit board 17 is a single-sided board where only one surface of the printed circuit board 17 forms the mounting surface 28. Electronic parts 27, such as a diode, are mounted on the mounting surface 28 so as to be accommodated in the case 12. Electrode terminals include an anode terminal 29 and two cathode terminals 30. The electrode terminals 29, 30 are accommodated in the case 12 and are attached to the mounting surface 28 by soldering. The anode terminal 29 and the cathode terminals 30 are in a plate-like shape.

The anode terminal 29 and the cathode terminals 30 are bent in a cranked shape in a side view. The electrode terminals 29, 30 have board-side end portions 29A, 30A and case-side end portions 29B, 30B at the opposite ends. The board-side end portions 29A, 30A are to be connected to the printed circuit board 17. The board-side end portions 29A, 30A are jointed to a wiring pattern not shown, thereby the electrode terminals 29, 30 are electrically connected to the electronic parts 27. The width of the anode terminal 29 is set substantially the same as that of the anode-connecting terminal 22. Similarly, the width of the cathode terminals 30 is set substantially the same as the cathode-connecting terminals 23.

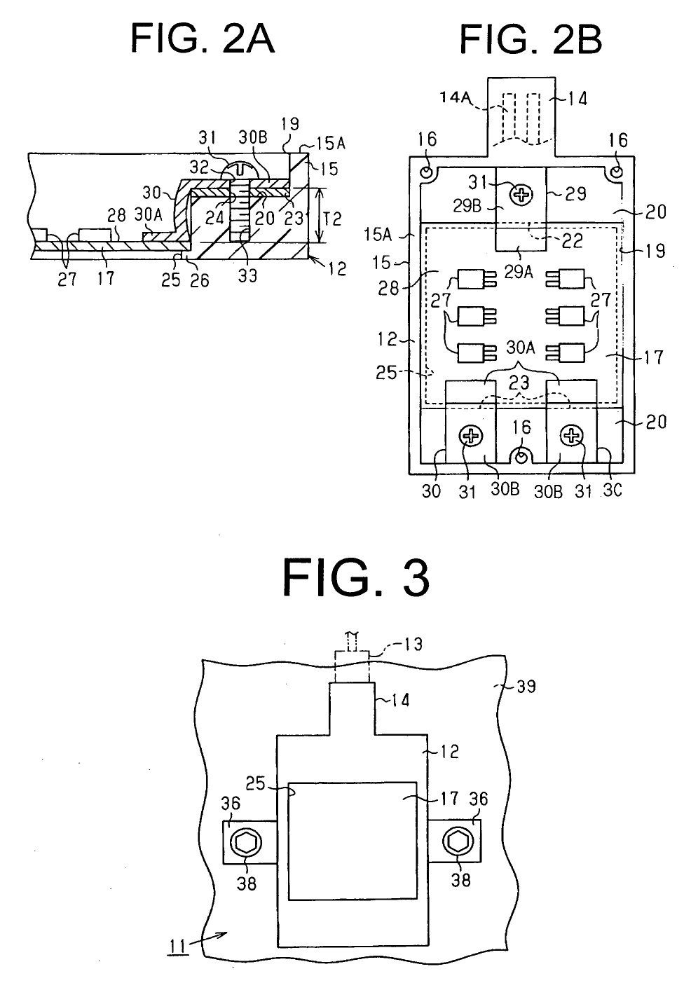

Each of the case-side end portions 29B, 30B has a second through hole 32 therethrough, respectively. The anode terminal 29 is connected to the anode-connecting terminal 22 by fastening the case-side end portion 29B with a second screw 31 as a fastening member to the anode-connecting terminal 22. The cathode terminal 30 is connected to the cathode-connecting terminal 23 by fastening the case-side end portion 30B with another second screw 31 to the cathode-connecting terminal 23. That is, the case-side end portions 29B, 30B are securely connected to the connecting terminals 22, 23 such. that the second screws 31 are inserted through the second through holes 32 and then screwed into the second screw holes 24, as shown in FIG. 2. The second screws 31 are inserted in threaded holes 33 formed in the stepped portions 20. Alternatively, the anode-connecting terminal 22 and the cathode-connecting terminal 23 may have corresponding plain holes instead of the second screw holes 24. In this case, nuts may be positioned below the plain holes and be connected to the stepped portions 20 by insert molding. Then, the anode-connecting terminal 22 and the anode terminal 29 may be securely connected through the nut and the second screw 31. Similarly, the cathode-connecting terminals 23 and the cathode terminals 30 may be securely connected through the nuts and the second screws 31.

The cathode terminal 30 has a board-side contacting surface in the board-side end portion 30A and a case-side contacting surface in the case-side end portion 30B. The board-side contacting surface faces the printed circuit board 17. The case-side contacting surface faces the cathode-connecting terminal 23 arranged on the stepped portion 20. In the cathode terminal 30, T1 represents the vertical distance of the board-side contacting surface in the board-side end portion 30A from the case-side contacting surface in the case-side end portion 30B. FIG. 2A shows a state where the printed circuit board 17 is accommodated in the case 12. As shown in FIG. 2A, T2 represents the vertical distance of the mounting surface 28 in the printed circuit board 17 from the upper surface in the cathode-connecting terminal 23 (the contacting surface facing the case-side end portion 30B). The distance T1 is set greater than the distance T2. The anode-connecting terminal 22 and the anode terminal 29 have the similar structure.

The electronic parts 27 are surface-mounted components and are electrically connected to the anode terminal 29 and the cathode terminals 30. As shown FIG. 2B, three electronic parts 27 are aligned in the longitudinal direction of the printed circuit board 17. The three electronic parts 27 are electrically connected in series. Two rows of three electronic parts are parallelly arranged in line in the longitudinal direction. Each row is electrically connected in parallel with each other.

The electronic parts 27 are electrically connected to the external terminal 14A of the connector portion 14 when the anode terminal 29 and the cathode terminal 30 are securely connected by the second screws 31.

As shown in FIG. 1, the metal plate 34 is attached to the case 12 by first screws 35 so as to cover the top opening 19. The metal plate 34 is formed in a rectangular shape in a plan view, and has two parallel sides. The metal plate 34 has plural first through holes 34A. Two first through holes 34A, 34A are formed at two corners adjacent to both ends of one of the short sides. Another first through hole 34A is formed at the middle of the other short side which is parallel to the short side defined by the two corners. Each of the first through holes 34A has a recess for accommodating the head of the first screw 35 in the outer surface of the metal plate 34. The metal plate 34 has a larger cross-sectional area than the top opening 19, and is adhered to the upper surface of the peripheral wall 15. Thereby, the case 12 is reliably hermetically closed. The anode-connecting terminal 22 and the cathode-connecting terminals 23 face the metal plate 34 when the metal plate 34 is attached to the case 12. Attaching portions 36 are formed with the metal plate 34. The attaching portions 36 are extended from the middle of the longer side of the metal plate 34 in the same plane.

Each of the attaching portions 36 includes an attaching hole 37 through which a fastening member (such as a screw) is inserted. The electronic components 11 are attached to an object (such as a vehicle frame) through the attaching portions 36. The metal plate 34 and the attaching portions 36 form a metal cover.

The following will describe the assembling process of the above-described electronic components. Firstly, the electronic parts 27 are mounted in advance on the printed circuit board 17 so as to prepare the printed circuit board 17 mounting the electronic parts 27. Then, the electrode terminals 29, 30 are connected to the printed circuit board 17 such that the board-side end portions 29A, 30A of the electrode terminals 29, 30 are soldered to the wiring pattern. Alternatively, the printed circuit board 17 is prepared, and the process for mounting the electronic parts 27 is performed simultaneously with the soldering of the board-side end portions 29A, 30A of the electrode terminals 29, 30 to the wiring pattern.

Next, an adhesive is applied to the peripheral portion 26 at the bottom of the case 12. Alternatively, an adhesive is applied to the periphery of the rear surface of the printed circuit board 17. Then, the printed circuit board 17 is placed on the peripheral portion 26 at the bottom of the case 12 by interposing the adhesive therebetween. At the same time, the case-side end portions 29B, 30B of the anode terminal 29 and the cathode terminals 30 are arranged so as to correspond to the anode-connecting terminal 22 and the cathode-connecting terminals 23, respectively. Then, the case-side end portions 29B, 30B of the electrode terminals 29, 30 are fastened to the connecting terminals 22, 23 with the second screws 31. Thus, the installation of the printed circuit board 17 mounting the electronic parts 27 to the case 12 is completed. Next, an adhesive is applied to the end face 15A of the peripheral wall 15, or alternatively, to the surface of the metal plate 34 facing the end face 15A of the peripheral wall 15. The metal plate 34 is attached to the case 12 by placing the metal plate 34 on the end face 15A of the peripheral wall 15 so as to cover the top opening 19. The manufacturing process of the electronic components 11 is completed by fastening the metal plate 34 to the case 12 with the first screws 35.

The following will describe the operation of the above-described electronic components. When utilizing the electronic components 11, fastening members 38 are inserted through the corresponding attaching holes 37, and then are screwed into attaching holes (not shown) formed in a vehicle frame 39. The vehicle frame 39 is an object to which the electronic components 11 are attached. In this case, even when the attaching portions 36 are fixed to the vehicle frame 39 by pressing and are deformed in fastening the attaching portions 36 with the fastening members 38, the printed circuit board 17 is not to be deformed. That is because the printed circuit board 17 is spaced apart from the metal plate 34. Therefore, generation of unnecessary stress due to deformation of the printed circuit board 17 is reduced in the printed circuit board 17. Defects in the electrically-connected structure of the mounted electronic parts 27 are reduced, accordingly.

When the electronic components 11 are attached to the vehicle frame 39, the surface of the metal plate 34 opposite to the printed circuit board 17 is in contact with the vehicle frame 39. The printed circuit board 17 is in a face-down state in which the mounting surface 28 of the printed circuit board 17 directs downward. In this state, substantially the entire surface of the rear surface of the printed circuit board 17 is exposed to the external air. When the vehicle frame 39 is vibrated in this state, the vibration may be transferred to the metal plate 34 and the metal plate 34 may be vibrated. However, the metal plate 34 is spaced apart from the printed circuit board 17 and the electrode terminals 29, 30, and the vibration of the metal plate 34 is not transferred to the printed circuit board 17 directly. Therefore, generation of unnecessary stress is reduced in the printed circuit board 17, and the defects are reduced in the electrically-connected structure of the mounted electronic parts 27.

When the electronic components 11 are activated, the connector 13 of the external device is inserted in and connected to the connector portion 14 of the electronic components 11. Then large current, for example, of 10 ampere is output from the external device. The large current is supplied to the electronic parts 27 through the anode-connecting terminal 22, the anode terminal 29, and the wiring pattern, thereby activating the electronic parts 27. In supplying the large current to the electronic parts 27 and activating the electronic parts 27, a large amount of heat is generated from the electronic parts 27. The heat generated from the electronic parts 27 is instantly radiated to the external air through the metal plate 34 and the bottom opening 25. Thereby, the rise in temperature of the electronic parts 27 is sufficiently prevented to the level without any trouble, and breakage of the electronic parts 27 is prevented.

The preferred embodiment has the following advantageous effects.

(1) The electrode terminals 29, 30 are formed in a plate-like shape and electrically connect the electronic parts 27 to the external terminal 14A of the connector portion 14. A plate-like electrode terminal has a wider cross-sectional area than a thin wire. The plate-like electrode terminals 29, 30 are widely in contact with the connecting terminals 22, 23, thereby reducing the electric-resistance at the contact portion. Therefore, large current flows through the plate-like electrode terminals 29, 30, unlike a thin lead-wire. When large current is supplied to the electronic parts 27 through the anode terminal 29, the electronic parts 27 are capable of being activated, without any hindrance.
(2) The stepped portions 20 are formed in the case 12, and the anode-connecting terminal 22 and the cathode-connecting terminal 23 are disposed on the stepped portions 20 by insert molding. The metal plate 34 is attached to the case 12 in a separated manner from the printed circuit board 17. Therefore, the metal plate 34 does not come into contact with the printed circuit board 17 and the connecting terminals 22, 23. Even when the attaching portions 36 are attached to the vehicle frame 39 by pressing and are deformed, generation of unnecessary stress is reduced in the printed circuit board 17, and the troubles in the electrically-connected structure is reduced in the mounted electronic parts 27.
(3) The electronic components 11 are attached to the vehicle frame 39. The vehicle frame 39 is vibrated frequently, and the vibration may be transferred to the metal plate 34. However, the transfer of the vibration to the printed circuit board 17 is suppressed, and the generation of unnecessary stress is reduced in the printed circuit board 17.
(4) The metal plate 34 serves as the metal cover for closing the top opening 19 of the case 12. The metal plate 34 radiates the heat instantly to the outside, compared to a case where the top opening 19 is closed by a resin cover. Thereby, the metal plate 34 is capable of preventing the breakage of the electronic components 11.
(5) In the stepped portions 20, the connecting terminals 22, 23 are disposed so as to face the metal plate 34. Therefore, before attaching the metal plate 34, the manufacturer can check the state of connection of the terminals 22, 23, 29, 30 while fastening the case-side end portions 29B, 30B of the electrode terminals 29, to the connecting terminals 22, 23 with the second screws 31. Therefore, the possibility of defective electrical contact due to failure in connection can be reduced between the anode terminal 29 and the anode-connecting terminal 22, and between the cathode terminal 30 and the cathode-connecting terminal 23.
(6) The case 12 has the bottom opening 25 for radiating the heat by opening the inside of the case 12 to the outside. The bottom opening 25 has a smaller cross-sectional area than the printed circuit board 17, and is covered by the rear surface of the printed circuit board 17. Therefore, when the electronic parts 27 are activated, the generated heat is radiated instantly from the surface opposite to the mounting surface 28 of the printed circuit board 17 to the outside through the bottom opening 25. Therefore, the rise in temperature of the electronic parts 27 is suppressed to a level without any trouble, thereby the breakage of the electronic parts 27 is to be prevented.
(7) The printed circuit board 17 is adhered to the peripheral portion 26 by the adhesive. The metal plate 34 and the end face 15A of the peripheral wall 15 are adhered by the adhesive. Therefore, inside of the case 12 for accommodating the printed circuit board 17 mounting the electronic parts 27 is hermetically closed.
(8) The anode terminal 29 and the cathode terminals 30 are fastened to the anode-connecting terminal 22 and the cathode-connecting terminals 23 with the second screws 31, respectively. Therefore, the connection is securely performed between the anode-side terminals 22, 29 and between the cathode-side terminals 23, 30, compared to a case where the connecting terminals 22, 23 are formed by tub terminals. Thereby the possibility of the defective connection can be reduced.
(9) The metal plate 34 is adhered to the end face 15A of the peripheral wall 15 by the adhesive. The metal plate 34 is fastened to the case 12 with the first screws 35. Therefore, even when load is applied to the case 12 at the insertion of the connector 13 of the external device to the connector portion 14, the load is not concentrated only to the adhesive interposed between the case 12 and the metal plate 34. The load is dispersed to the area fastened by the first screws 35. Therefore, the adhesive is prevented from being unglued due to the load at the insertion of the connector 13.
(10) T1 represents the vertical distance of the board-side contacting surface in the board-side end portion 30A from the case-side contacting surface in the case-side end portion 30B. T2 represents the vertical distance from the mounting surface 28 in the printed circuit board 17 from the upper surface in the cathode-connecting terminal 23 (the contacting surface facing the case-side end portion 30B) in the accommodated state in the case 12. The distance T1 is set greater than the distance T2. The anode-connecting terminal 22 and the anode terminal 29 have the similar structure. Therefore, in manufacturing the electronic components 11, the printed circuit board 17 is not spaced apart from the peripheral portion 26 at the bottom of the case 12.

The present invention is not restricted to the above-described embodiment, and may be modified or embodied as follows.

The opening area of the bottom opening 25 for heat radiation may be modified. The opening area of the bottom opening 25 is set appropriately, as long as the rear surface of the printed circuit board 17 is supported, and heat generated from the electronic parts 27 is radiated sufficiently to the outside. For example, the opening area of the bottom opening 25 may be set two-thirds of the area of the rear surface of the printed circuit board 17.

Instead of forming the bottom opening 25, a metal plate may be arranged by insert molding at the bottom of the case 12 so as to expose the surface of the metal plate. In this case, the printed circuit board 17 may be placed on the metal plate. When heat is generated from the electronic parts 27, the heat is radiated from the printed circuit board 17 to the outside through the metal plate.

The printed circuit board 17 may not be attached in a face-down state to the vehicle frame 39 as the object to which the electronic components 11 are attached. For example, the attaching portion 36 may be formed in a cranked shape and extended along the peripheral wall 15 of the case 12. An attaching hole may be formed at the end of the attaching portion. A fastening member may be inserted in the attaching hole, and be screwed into an unshown screw hole formed in the vehicle frame. With such a construction, the printed circuit board 17 may be set in a face-up state, by attaching the electronic components by fastening the end of the attaching portion to the vehicle frame as the object. In this case, the height of the attaching portion 36 is set greater than the thickness of the case 12 so that the bottom of the case 12 does not directly contact the object. Thereby the vibration is not transferred to the printed circuit board 17.

Instead of utilizing the metal plate 34 as the metal cover, for example, a metal cover in a box-shape may be utilized to cover the top opening 19. The box-shaped metal cover may cover the top opening 19 so as to hermetically close the case 12. In this case, an adhesive may be interposed between the lower end of the metal cover and end face 15A of the peripheral wall 15.

In the preferred embodiment, the second screws 31 are utilized as the fastening member connecting the board-side end portions 29A, 30A of the electrode terminals 29, 30 to the connecting terminals 22, 23. The fastening member is not limited to a screw, and such as a bolt may be applied as the fastening member, instead of the second screws 31.

The type of the electronic parts mounted on the printed circuit board may be modified. A printed circuit board on which a switching device or a condenser is mounted may be accommodated in the case 12.

The type of the printed circuit board on which the electronic parts are mounted may be modified. Such as a ceramic circuit board or a metal circuit board may be applied.

The object to which the electronic components 11 are attached is not limited to a vehicle frame. Such as a part of a machine tool may serve as an object to which the electronic components 11 are attached.

The attaching portion 36 may be omitted. In this case, the outer surface of the metal plate 34 may serve as an attaching portion. An adhesive may be applied to the outer surface of the metal plate 34, and the outer surface of the metal plate 34 may be adhered to an object to which the electronic components 11 are attached. The object may be other than a vehicle frame.

Therefore, the present examples and embodiments are to be considered as illustrative and not restrictive, and the invention is not to be limited to the details given herein but may be modified within the scope of the appended claims.

What is claimed is:

1. Electronic components comprising:
a case including a connector portion and an opening, wherein the connector portion has an external terminal therein;
a circuit board accommodated in the case;
electronic parts mounted on the circuit board;
a plate-like electrode terminal accommodated in the case and electrically connected to the electronic parts, wherein the plate-like electrode terminal includes a board-side end portion and a case-side end portion, wherein the board-side end portion is connected to the circuit board;
a metal cover attached to the case to close the opening of the case such that the metal cover is spaced away from the circuit board and the electrode terminal;
a stepped portion formed in the case;
a connecting terminal arranged on the stepped portion, wherein the connecting terminal is formed integrally with the external terminal; and
a fastening member for connecting the case-side end portion to the case, thereby the fastening member electrically connects the case-side end portion to the connecting terminal.

2. The electronic components according to claim 1, further comprising a bottom opening formed at the bottom of the case for heat radiation, wherein the circuit board closes the bottom opening in a state where the electronic parts are accommodated in the case.

3. The electronic components according to claim 2, wherein a periphery of a rear surface of the circuit board is adhered by an adhesive to a peripheral portion formed around the bottom opening.

4. The electronic components according to claim 1, the plate-like electrode terminal is formed in a cranked shape.

5. The electronic components according to claim 1, wherein the circuit board has a mounting surface on which the electronic parts are mounted, wherein the electrode terminal has a board-side contacting surface in the board-side end portion and a case-side contacting surface in the case-side end portion, and wherein a vertical distance of the board-side contacting surface from the case-side contacting surface is greater than a vertical distance of the mounting surface in the circuit board from a surface in the connecting terminal facing the electrode terminal.

6. The electronic components according to claim 1, wherein the case is formed in a rectangular shape, and wherein the stepped portion is formed at each longitudinal end of the case, respectively, so as to extend along the short side of the case.

7. The electronic components according to claim 6, wherein the connecting terminal includes an anode-connecting terminal and two cathode-connecting terminals, wherein the anode-connecting terminal is arranged on the stepped portion at one end of the case, and the cathode-connecting terminals are arranged on the stepped portion at the other end of the case.

8. The electronic components according to claim 1, wherein the case is made of resin.

9. The electronic components according to claim 1, further comprising an attaching portion formed with the metal cover, wherein the electronic components are attached to an object through the attaching portion.

10. The electronic components according to claim 1, further comprising:
a first screw hole formed in the case;
a first through hole formed through the metal cover at a corresponding position to the first screw hole; and
a first screw inserted in the first screw hole through the first through hole to connect the metal cover to the case.

11. The electronic components according to claim 10, further comprising:
a second screw hole formed in the stepped portion;
a second through hole formed through the case-side end portion of the electrode terminal; and
a second screw as the fastening member inserted in the second screw hole through the second through hole.
